(19) United States
(12) Patent Application Publication
(10) Pub. No.: US 2014/0293556 A1
(43) Pub. Date: Oct. 2, 2014

(54) POWER SUPPLY DEVICE

(71) Applicant: TDK Corporation, Tokyo (JP)

(72) Inventors: Mieko Fujisaki, Minato (JP); Kazuya Takahashi, Minato (JP); Natsuko Omomo, Minato (JP)

(73) Assignee: TDK Corporation, Tokyo (JP)

(21) Appl. No.: 14/190,180

(22) Filed: Feb. 26, 2014

(30) Foreign Application Priority Data
Mar. 27, 2013 (JP) 2013-066442
Mar. 29, 2013 (JP) 2013-071131

(51) Int. Cl. H05K 7/14

(52) U.S. Cl. CPC H05K 7/1417
USPC 361/752

(57) ABSTRACT

A power supply device includes a circuit board that has an arrangement surface and a rear surface opposite to the arrangement surface and that has a through hole. An insertion mounted circuit component, a connector and a surface mounted light emitting component that is provided for confirming an operation of the power supply device are assembled on the arrangement surface. A chassis holds the circuit board from the sides and the rear surface of the circuit board and has an opening to expose the connector. The surface mounted light emitting component is surface mounted on the rear surface of the circuit board. The through hole is provided near the surface mounted light emitting component so as to guide light emitted from the surface mounted light emitting component toward the opening of the chassis.

### CROSS-REFERENCE TO RELATED APPLICATION

This application claims priority to Japanese Patent Application Nos. 2013-066442 filed Mar. 27, 2013, and 2013-071131 filed Mar. 29, 2013 which are hereby expressly incorporated by reference herein in their entirety.

### BACKGROUND

The present invention relates to a power supply device that is provided with a circuit board and a chassis. Specifically, a light emitting component, such as a light emitting diode (LED), for confirming/displaying an operation state (operation state confirmation) of the power supply device is mounted on the circuit board. The chassis holds the circuit board.

As disclosed in Japanese Patent Publication Number 2002-315307, a power supply device, in which a LED for displaying an operation state is provided, is known. The power supply device is configured with a DC-DC converter module that has a wiring board on which an electric component is mounted and a shield housing that contains the wiring board. In this case, the LED for displaying an operation state is provided on the wiring board of the DC-DC converter module. This power supply device enables confirmation of an operation state of the DC-DC converter module because the LED emits light.

However, the above conventional power supply device has the following problems. An insertion mounted LED is used as the LED for displaying an operation state in this power supply device. Specifically, a connection terminal that is formed by a metal wire material is attached to a base end of a light emitting member of the insertion mounted LED. Further, in this power supply device, many insertion mounted electric components are used in addition to the insertion mounted LED for displaying an operation state. Therefore, the insertion mounted electric components need to be replaced with surface mounted electric components to miniaturize the power supply device. Further, when the insertion mounted electric component is attached to the wiring board, a connection terminal needs to be inserted into an insertion hole that is formed on the wiring board from a front surface side to a rear surface side. Further, a tip of the connection terminal, which passes through the insertion hole, located on the rear surface side needs to be fixed to a wiring pattern by soldering. Therefore, the insertion mounted electric components need to be replaced with the surface mounted electric components to improve assembling efficiency. In consideration of the above described matters, a configuration in which a surface mounted LED is used and attached to the rear surface side instead of using the insertion mounted LED can be adopted. However, when this configuration is adopted, a problem of deterioration in visibility occurs. That is, because light that is emitted from the surface mounted LED is shaded by the wiring board, the light cannot be visually recognized from the front surface side of the wiring board.

### SUMMARY

Embodiments of the present invention attempt to solve the problems explained above. An object of the present invention is to provide a power supply device that can improve manufacturing efficiency while fully securing the visibility of light that is emitted from a light emitting component.

To achieve the above object, a power supply device according to one aspect of the present invention includes: a circuit board that has an arrangement surface and a rear surface opposite to the arrangement surface and that has a through hole, the circuit board having an insertion mounted circuit component, a connector and a surface mounted light emitting component that is provided for confirming an operation of the power supply device are assembled thereon; and a chassis that holds the circuit board from sides and the rear surface of the circuit board and that has an opening to expose the connector. The surface mounted light emitting component is assembled on the rear surface of the circuit board. The through hole is provided proximate (in a vicinity of) the surface mounted light emitting component so as to guide light emitted from the surface mounted light emitting component toward the opening of the chassis.

Further, in the power supply device according to the aspect of the present invention, the surface mounted light emitting component is configured with a light emitting member and an optical dispersion member attached to the light emitting member. An edge of the optical dispersion member is located inside of the through hole in a plan view.

Further, in the power supply device according to the aspect of the present invention, the surface mounted light emitting component is a light emitting diode (LED).

In the power supply device according to the aspect of the present invention, a light emitting component for confirming an operation of the power supply device is composed of a surface mounted LED. The surface mounted LED is placed on a connection surface (a rear surface) of a circuit board. Unlike a configuration in which an insertion mounted LED has a connection terminal formed by a metal wire material, an automated mounting process can be used for the surface mounted LED by using, for example, a mounter. As a result, the manufacturing efficiency can be improved. Further, in the power supply device according to the aspect of the present invention, because a through hole is formed near a position on which the surface mounted LED is mounted in the circuit board, light, which is emitted from the surface mounted LED that is mounted on the connection surface of the circuit board, passes through the through hole and reaches a side of an arrangement surface (a front surface) of the circuit board. As a result, the light can be irradiated toward an open area of a chassis. Therefore, according to the power supply device, the visibility of the light that is emitted from the surface mounted LED as a light emitting component can be adequately secured. As a result, when a user looks at the circuit board from the open area of the chassis, the user can certainly and visually recognize a light emitting state of the surface mounted LED. Therefore, an operation state of the power supply device can be surely confirmed.

In the power supply device according to the aspect of the present invention, because the surface mounted LED is provided with the main body that emits the light and the optical dispersion member that is attached to the main body, the light can be dispersed by the optical dispersion member. Therefore, as compared with a configuration in which the light is emitted in only a narrow range, the dispersed light certainly passes though the through hole and reaches the side of the arrangement surface. As a result, the dispersed light can be certainly irradiated to the open area of the chassis.

Further, an edge of the optical dispersion member is located inside of the through hole in a plan view. In other words, the surface mounted LED is placed at a position in which a tip of the optical dispersion member projects toward a center of the through hole from an edge of the through hole in a state in which the circuit board is seen from the side of the arrangement surface. Therefore, much of the light that is dispersed by the optical dispersion member can pass through the through hole and be irradiated toward the open area of the chassis. As a result, the light emitting state of the surface mounted LED can be more surely and visually recognized.

A power supply device according to another aspect of the present invention includes: a circuit board that has an arrangement surface and a rear surface opposite to the arrangement surface and that has a through hole, the circuit board having an insertion mounted circuit component, a connector and a surface mounted light emitting component that is provided for confirming an operation of the power supply device are assembled thereon; a chassis that holds the circuit board from sides and the rear surface of the circuit board, that has an opening to expose the connector and that has a reflective member facing the rear surface of the circuit board and the surface mounted light emitting component; and a gap that is provided between the rear surface of the circuit board and the reflective member. The surface mounted light emitting component is assembled on the rear surface of the circuit board so as to emit light toward the reflective member. The through hole is provided proximate (in a vicinity of) the surface mounted light emitting component so as to guide the light reflected by the reflective member toward the opening of the chassis.

Further, in the power supply device according to the aspect of the present invention, the surface mounted light emitting component is a light emitting diode (LED).

Further, in the power supply device according to the aspect of the present invention, the reflective member is a surface of the chassis.

In the power supply device according to the aspect of the present invention, a light emitting component for confirming an operation of the power supply device is composed of a surface mounted LED. The surface mounted LED is placed on a connection surface (a rear surface) of a circuit board. Unlike a configuration in which an insertion mounted LED has a connection terminal formed by a metal wire material, an automated mounting process can be used for the surface mounted LED by using, for example, a mounter. As a result, the manufacturing efficiency can be improved. Further, in the power supply device according to the aspect of the present invention, because a through hole is formed in the circuit board, light, which is emitted from the surface mounted LED that is mounted on the connection surface of the circuit board, is reflected by the reflective member so as to pass the reflected light through the through hole. Therefore, the reflected light reaches a side of an arrangement surface (a front surface) of the circuit board. As a result, the light can be irradiated toward an open area of a chassis. Therefore, according to the power supply device, the visibility of the light that is emitted from the surface mounted LED as a light emitting component can be adequately secured. As a result, when a user looks at the circuit board from the open area of the chassis, the user can certainly and visually recognize a light emitting state of the surface mounted LED. Therefore, an operation state of the power supply device can be surely confirmed.

In the power supply device according to the aspect of the present invention, the reflective member is a bottom surface of the chassis. Thus, as compared with a configuration in which the reflective member is formed by a separate member that is different from the bottom surface of the chassis, it is possible to reduce a manufacturing cost of the power supply device because the separate reflective member is not necessary.

### BRIEF DESCRIPTION OF THE DRAWINGS

FIG. 1 is a perspective view that shows a configuration of a power supply device 1 according to an embodiment of the present invention.

FIG. 2 is a perspective view that shows a configuration of a power supply circuit mounting body 2 according to an embodiment of the present invention.

FIG. 3 is a cross sectional view that shows a mounting state of a circuit component 31 in the power supply circuit mounting body 2 according to an embodiment of the present invention.

FIG. 4 is a perspective view of a surface mounted LED 33 according to an embodiment of the present invention.

FIG. 5 is a plan view of a circuit board 2a and the surface mounted LED 33 viewed from a side of an arrangement surface 21 according to an embodiment of the present invention.

FIG. 6 is a plan view of the circuit board 2a and the surface mounted LED 33 viewed from a side of a connection surface 22 according to an embodiment of the present invention.

FIG. 7 is a cross sectional view of the power supply device 1 along line A-A in FIG. 5 according to an embodiment of the present invention.

FIG. 8 is a perspective view that shows a configuration of a power supply device 10 according to an embodiment of the present invention.

FIG. 9 is a perspective view that shows a configuration of the power supply circuit mounting body 20 according to an embodiment of the present invention.

FIG. 10 is a cross sectional view that shows a mounting state of the circuit component 31 in the power supply circuit mounting body 20 according to an embodiment of the present invention.

FIG. 11 is a perspective view of a surface mounted LED 330 according to an embodiment of the present invention.

FIG. 12 is a plan view of the circuit board 2a and the surface mounted LED 330 viewed from a side of an arrangement surface 21 according to an embodiment of the present invention.

FIG. 13 is a plan view of the circuit board 2a and the surface mounted LED 330 viewed from a side of a connection surface 22 according to an embodiment of the present invention.

FIG. 14 is a cross sectional view of the power supply device 10 along line A-A in FIG. 12 according to an embodiment of the present invention.

FIG. 15 is a cross sectional view of a configuration of the power supply device 101 according to an embodiment of the present invention.

### DESCRIPTION OF EXEMPLARY EMBODIMENTS

### First Embodiment

A power supply device according to a first embodiment of the present invention will be explained below with reference to the drawings. First, a configuration of a power supply device 1 will be explained below.

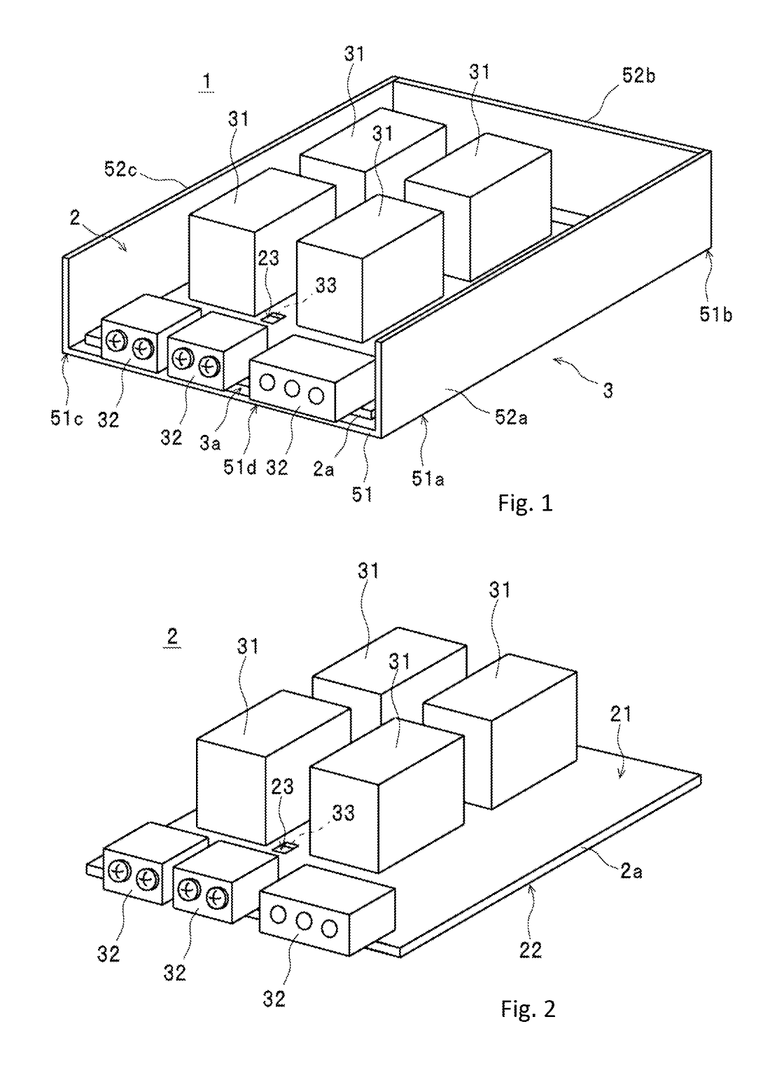

The power supply device 1 shown in FIG. 1 is, for instance, a device that supplies power to electronic equipment such as a measurement device. The power supply device 1 is configured so as to be suitable for use by being attached to a cabinet or a rack. Specifically, the power supply device 1 is provided with a power supply circuit mounting body 2 and a chassis 3.

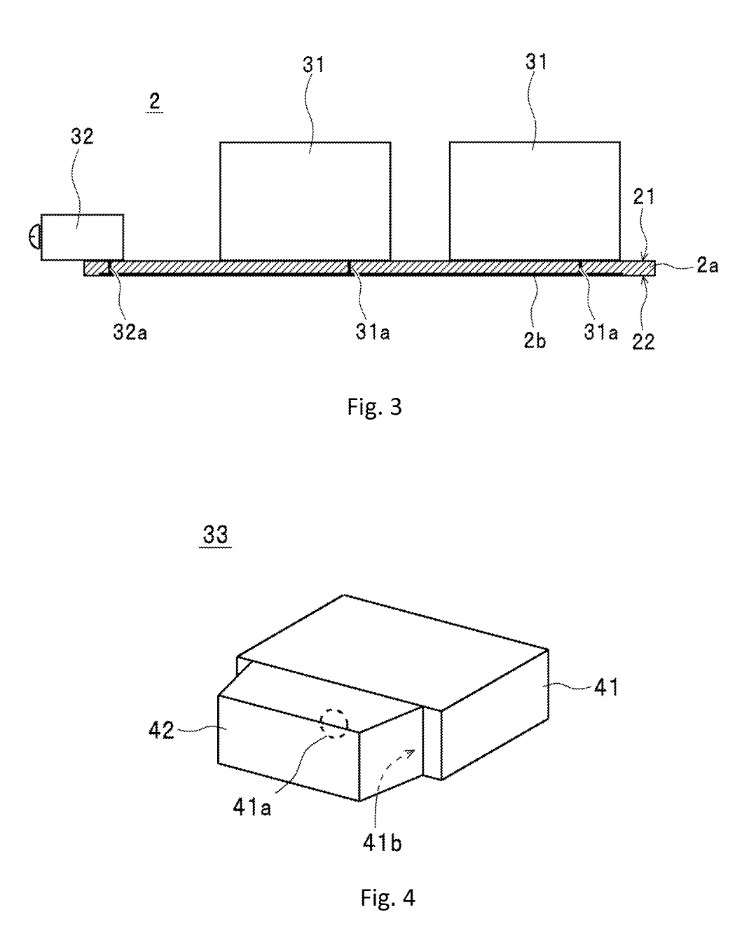

As shown in FIG. 2, the power supply circuit mounting body 2 is configured with a circuit board 2a on which circuit components 31, which configure a power supply circuit, a connector (connectors) 32 and a surface mounted LED 33 are mounted. In this case, as shown in FIG. 3, body portions of the circuit components are placed on a front surface side of the circuit board 2a (also referred to as “an arrangement surface 21” below). Because terminals 31a are inserted in insertion holes that are formed in the circuit board 2a and are soldered on a rear surface side (also referred to as “a connection surface 22” below) of the arrangement surface 21, the circuit components 31 are mounted on the circuit board 2a. Therefore, solder connection sections in which the terminals 31a are soldered to the circuit board 2a are formed on the connection surface 22 of the circuit board 2a. Further, each drawing roughly shows an outer shape of each of the circuit components 31.

The connector 32 corresponds to a terminal that is used for connecting to a power source circuit that is configured with the power supply circuit mounting body 2. As shown in FIG. 2, the connector 32 is mounted on one end of the circuit board 2a. Further, as shown in FIG. 3, a body portion of the connector 32 is placed on a side of the arrangement surface 21 of the circuit board 2a. Because a terminal 32a is inserted in an insertion hole that is formed in the circuit board 2a and is soldered on a side of the connection surface 22, the connector 32 is mounted on the circuit board 2a.

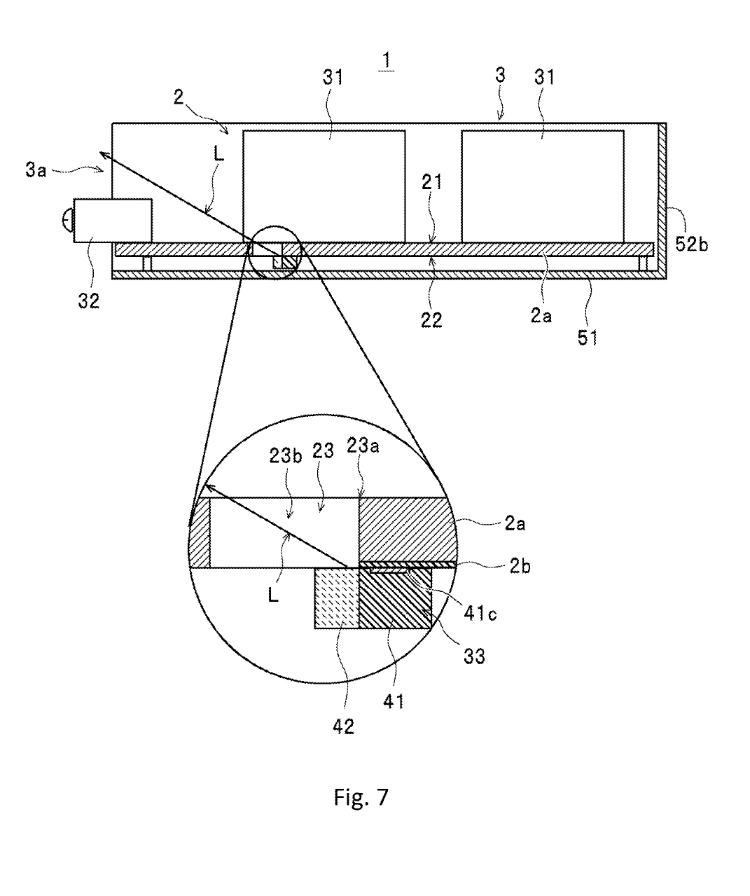

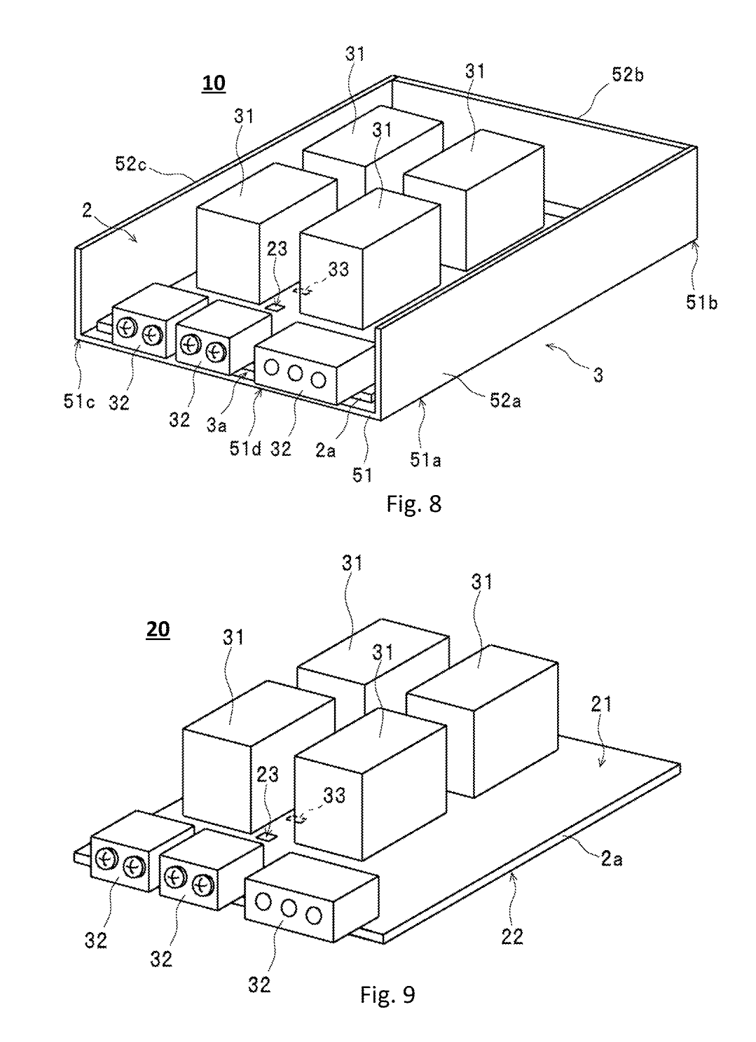

The surface mounted LED 33 corresponds to a light emitting component for confirming an operation of the power supply device 1. As shown in FIGS. 6 and 7, the surface mounted LED 33 is placed on the connection surface 22 of the circuit board 2a and emits light according to an operation state of the power supply device 1 (specifically, a power source circuit that is configured with the power supply circuit mounting body 2). Further, as shown in FIG. 4, the surface mounted LED 33 is provided with a main body (a light emitting member) 41 and an optical dispersion member 42.

As shown in FIG. 4, the main body 41 is provided with a LED element 41a that emits light L (refer to FIG. 7) and is formed in a box shape. Further, as shown in FIG. 7, a connection terminal 41c that is in a plate shape is placed on a bottom surface of the main body 41. Because the connection terminal 41c is soldered to the solder connection section that is provided on the connection surface 22 of the circuit board 2a, the surface mounted LED 33 is electrically connected to a wiring pattern 2b that is provided on the connection surface 22 of the circuit board 2a. Further, the surface mounted LED 33 is configured as a side view type and emits the light L from a side 41b (refer to FIG. 4) of the main body 41.

As shown in FIG. 4, the optical dispersion member 42 is attached to the side 41b of the main body 41. The optical dispersion member 42 is, as an example, formed with transparent (or translucent) resin and has a function to make the light L reflect, scatter and disperse. Specifically, the light L is emitted from the side 41b of the main body 41. In this case, the optical dispersion member 42 that is formed with a colored resin can also be adopted.

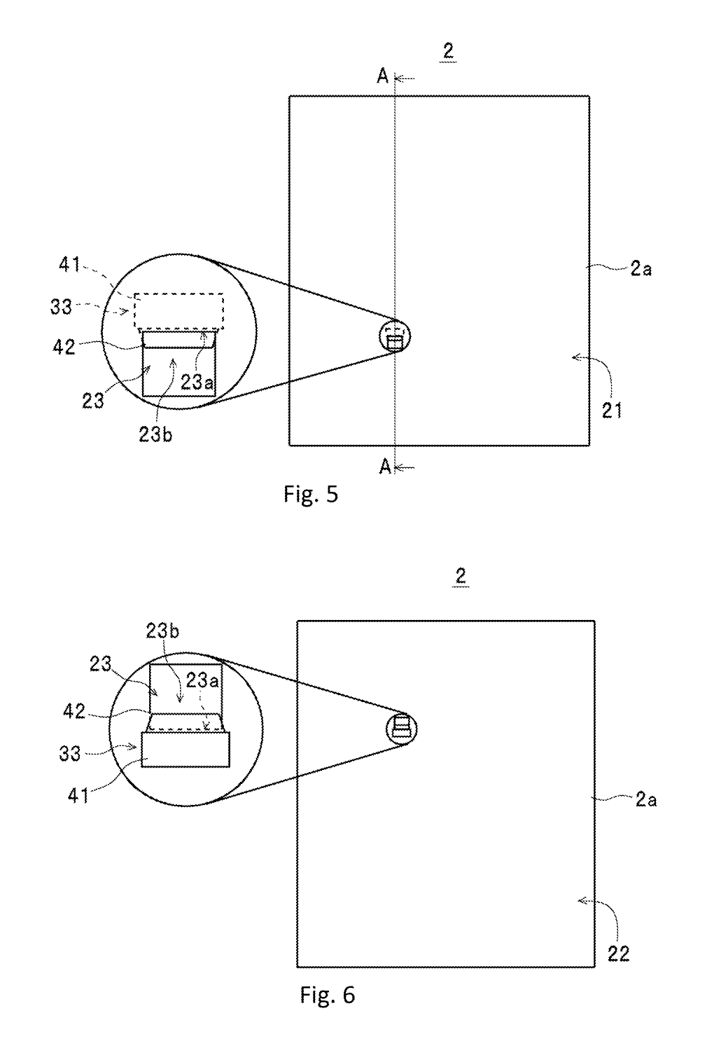

As shown in FIGS. 5-7, in the power supply device 1, a through hole 23 is formed to pass through from the arrangement surface 21 to the connection surface 22 of the circuit board 2a near a mounting position of the surface mounted LED 33 on the circuit board 2a. In this case, as shown in FIGS. 5 and 6, the through hole 23 is, as an example, formed in a rectangular shape in a plan view. Further, as shown in FIG. 7, the through hole 23 is regulated with respect to its size and position so as to make the light L that is emitted from the surface mounted LED 33 pass through from the connection surface 22 to the arrangement surface 21 of the circuit board 2a. As a result, it is possible to irradiate the light L toward an open area 3a of the chassis 3 as explained below.

As shown in FIG. 5, in the power supply device 1, when seen from above toward the arrangement surface of the circuit board 2a, the surface mounted LED 33 is placed at a position in which a tip of the optical dispersion member 42 of the surface mounted LED 33 projects toward a center 23b of the through hole 23 from an edge 23a of the through hole 23 that is formed in the circuit board 2a.

In this case, in the power supply device 1, the surface mounted LED 33 is used as the light emitting component for confirming an operation of the power supply device 1. As a result, mounting can be effectively performed with a mounter for mounting a surface mounted component. Therefore, the manufacturing efficiency can be improved as compared with a case in which an insertion mounted LED that has a connection terminal formed with a metal wire material is used.

As shown in FIG. 1, the chassis 3 is provided with a main plate 51 and side walls 52a-52c that are respectively established on three outer circumference edges 51a-51c of the main plate 51. Further, the chassis 3 is configured so as to be able to hold the power supply circuit mounting body 2 on which the circuit components 31, the connectors 32 and the surface mounted LED 33 are mounted. In this case, a circumference edge 51d of the main plate 51 corresponds to the open area 3a that is open without a side wall. In a state in which the power supply circuit mounting body 2 is held by the chassis 3, the connector 32 that is mounted on the circuit board 2a is exposed at the open area 3a. The main plate 51 and the side walls 52a-52c explained above are, as an example, integrally formed as the chassis 3 by pressing a steel plate that is coated by galvanization.

Next, a method of using and operating the power supply device 1 will be explained below with reference to the drawings.

The power supply device 1 is, for instance, used by being attached to a cabinet or a rack. In this case, from the point of workability when a power cable is connected to the connector 32 of the power supply device 1, the power supply device 1 is placed and attached so as to make the connector 32 face to a front side (a near side) of the cabinet and the rack.

Next, the power supply device 1 is operated by connecting the power cable to the connector 32. Then, the power supply device 1 starts to supply electric power. As a result, the LED element 41a of the main body 41 in the surface mounted LED 33 emits the light L according to an operation state of the power source circuit and the light L is emitted from the side 41b of the main body 41.

In the above case, the light L that is emitted from the side 41b enters the optical dispersion member 42 that is attached on the side 41b of the main body 41 and is reflected and scattered by the optical dispersion member 42. As a result, the light L is dispersed in each direction.

Because the through hole 23 is formed near the mounting position of the surface mounted LED 33 that is mounted on the circuit board 2a, the light L that is emitted from the surface mounted LED 33 that is placed on the connection surface 22 (a rear surface) of the circuit board 2a passes through the through hole 23 and reaches the side of arrangement surface 21 of the circuit board 2a. As a result, a part of the light L is irradiated toward the open area 3a of the chassis 3. Further, as explained above, because the light L is dispersed by the optical dispersion member 42, the light L passes through the through hole 23 and surely reaches the side of the arrangement surface 21. Further, because the tip of the optical dispersion member 42 in the surface mounted LED 33 projects toward the center 23b from the edge 23a of the through hole 23, most of the light L that is dispersed by the optical dispersion member 42 passes through the through hole 23 and is irradiated toward the open area 3a of the chassis 3.

Next, the light L (that is, a light emitting state of the surface mounted LED 33) emitted from the surface mounted LED 33 that is irradiated as explained above is visually recognized from the side of the open area 3a of the chassis 3. As a result, the operation state of the power source circuit may be confirmed.

In the power supply device 1 according to the first embodiment of the present invention, a light emitting component for confirming an operation of the power supply device 1 is composed of the surface mounted LED 33. The surface mounted LED 33 is placed on the connection surface 22 (a rear surface) of a circuit board 2a. Unlike a configuration in which an insertion mounted LED has a connection terminal formed by a metal wire material, an automated mounting process can be used for the surface mounted LED 33 by using, for example, a mounter. As a result, the manufacturing efficiency can be improved. Further, in the power supply device 1 according to the first embodiment of the present invention, because the through hole 23 is formed near a position on which the surface mounted LED 33 is mounted in the circuit board 2a, the light L, which is emitted from the surface mounted LED 33 that is mounted on the connection surface 22 of the circuit board 2a, passes through the through hole 23 and reaches the side of the arrangement surface 21 (a front surface) of the circuit board 2a. As a result, the light L can be irradiated toward the open area 3a of the chassis 3. Therefore, according to the power supply device 1, the visibility of the light L that is emitted from the surface mounted LED 33 as a light emitting component can be adequately secured. As a result, when a user looks at the circuit board 2a from the open area 3a of the chassis 3, the user can certainly and visually recognize a light emitting state of the surface mounted LED 33. Therefore, an operation state of the power supply device 1 (the power supply circuit mounting body 2) can be surely confirmed.

Further, in the power supply device 1 according to the first embodiment, because the surface mounted LED is provided with the main body 41 that emits the light L and the optical dispersion member 42 that is attached to the main body 41, the light L can be dispersed by the optical dispersion member 42. Therefore, as compared with a case in which the light L is emitted in only a narrow range, a light quantity that passes through the through hole 23 and reaches the side of the arrangement surface 21 can be increased.

Further, in the power supply device 1 according to the first embodiment, when seen from above toward the arrangement surface 21 of the circuit board 2a, the surface mounted LED 33 is placed at the position in which the tip of the optical dispersion member 42 projects toward the center 23b from the edge 23a of the through hole 23. As a result, much of the light L that is dispersed by the optical dispersion member 42 can pass through the through hole 23 and be irradiated toward the open area 3a of the chassis 3. As a result, the light emitting state of the surface mounted LED 33 can be visually recognized more certainly.

The surface mounted LED 33 and the configuration of the through hole 23, through which the light L that is emitted from the surface mounted LED 33 passes, are not limited to the first embodiment explained above. For instance, a configuration in which a surface mounted LED that is not provided with the optical dispersion member 42 can also be adopted instead of the surface mounted LED 33 that is provided with the optical dispersion member 42. Further, although the through hole 23 is formed in the rectangular shape in the plan view as explained above, the shape of the through hole 23 in the plan view is not limited to the rectangular shape. The through hole 23 can be formed in an arbitrary shape such as a circular shape (or a semicircular shape), an elliptical shape (or a semielliptical shape), a square shape, a slit shape or a mesh shape.

Further, although the chassis 3 in which a top area that is opposite to the main plate 51 is open as explained above is used, a configuration in which a cover for covering the top open area can be provided, i.e., a configuration, in which a casing that has a chassis 3 and the cover are used, can also be adopted.

### Second Embodiment

A power supply device according to a second embodiment of the present invention will be explained below with reference to the drawings. First, a configuration of a power supply device 10 will be explained below.

The power supply device 10 shown in FIG. 8 is, for instance, a device that supplies power to electronic equipment such as a measurement device. The power supply device 10 is configured so as to be suitable for use by being attached to a cabinet or a rack. Specifically, the power supply device 10 is provided with a power supply circuit mounting body 20 and a chassis 3.

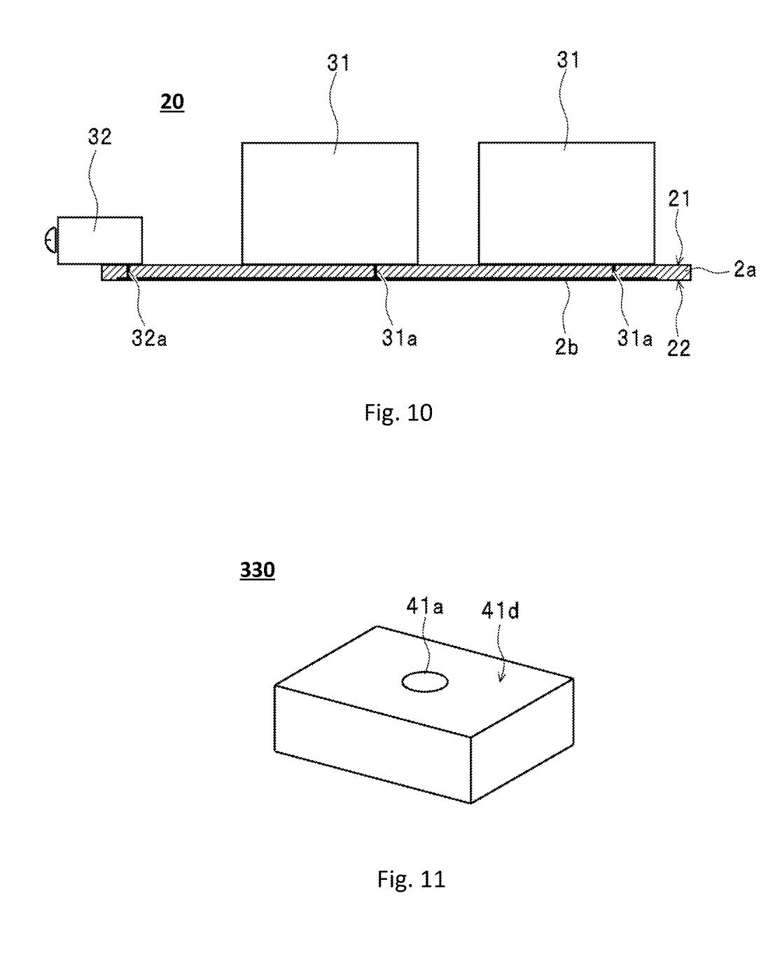

As shown in FIG. 9, the power supply circuit mounting body 20 is configured with a circuit board 2a on which circuit components 31, which configure a power supply circuit, a connector (connectors) 32 and a surface mounted LED 33 are mounted. In this case, as shown in FIG. 10, body portions of the circuit components 31 are placed on a front surface side of the circuit board 2a (also referred to as “an arrangement surface 21” below). Because terminals 31a are inserted in insertion holes that are formed in the circuit board 2a and are soldered on a rear surface side (also referred to as “a connection surface 22” below) of the arrangement surface 21, the circuit components 31 are mounted on the circuit board 2a. Therefore, solder connection sections in which the terminals 31a are soldered to the circuit board 2a are formed on the connection surface 22 of the circuit board 2a. Further, each drawing roughly shows an outer shape of each of the circuit components 31.

The connector 32 corresponds to a terminal that is used for connecting to a power source circuit that is configured with the power supply circuit mounting body 2. As shown in FIG. 9, the connector 32 is mounted on one end of the circuit board 2a. Further, as shown in FIG. 10, a body portion of the connector 32 is placed on a side of the arrangement surface 21 of the circuit board 2a. Because a terminal 32a is inserted in an insertion hole that is formed in the circuit board 2a and is soldered on a side of the connection surface 22, the connector 32 is mounted on the circuit board 2a.

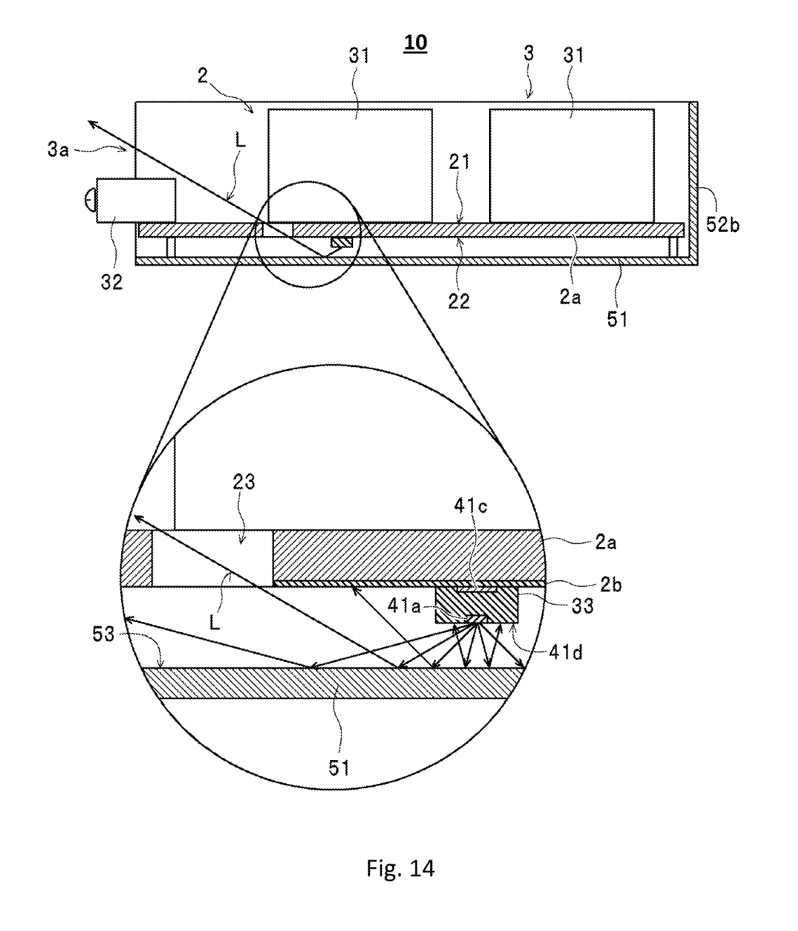

The surface mounted LED 33 corresponds to a light emitting component for confirming an operation of the power supply device 10. As shown in FIGS. 13 and 14, the surface mounted LED 33 is placed on the connection surface 22 of the circuit board 2a and emits light according to an operation state of the power supply device 10 (specifically, a power source circuit that is configured with the power supply circuit mounting body 20).

Further, as shown in FIG. 11, the surface mounted LED 33 is formed in a box shape and an LED element 41a that emits light L (refer to FIG. 14) is placed in a top surface 41d (an upper surface in FIG. 11). In this case, as shown in FIG. 14, the surface mounted LED 33 is placed on the connection surface 22 in a state in which the light L is emitted toward an inner surface 53 (that corresponds to a counter-face surface and a bottom surface) of a main plate 51 of the chassis that face the connection surface 22 of the circuit board 2a, i.e., in a state in which the top surface 41d faces the inner surface 53 of the main plate 51. Further, as shown in FIG. 14, a connection terminal 41c in a plate shape is placed on a bottom surface (an upper surface in FIG. 14) of the surface mounted LED 33. Because the connection terminal 41c is soldered to the solder connection section that is provided on the connection surface 22 of the circuit board 2a, the surface mounted LED 33 is electrically connected to a wiring pattern 2b that is provided on the connection surface 22 of the circuit board 2a.

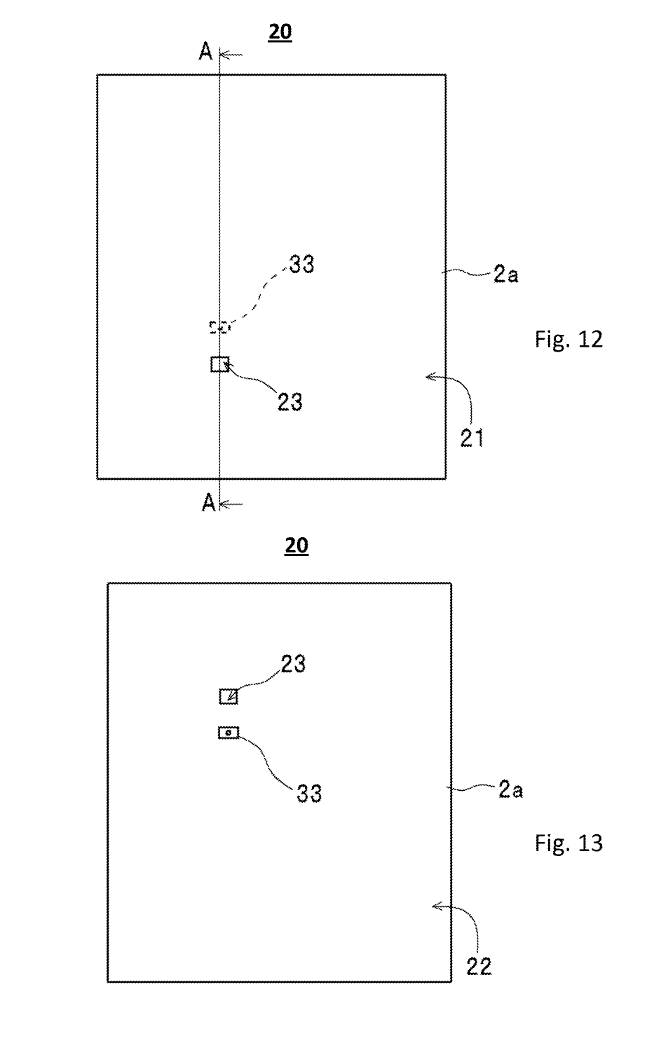

As shown in FIGS. 12-14, in the power supply device 10, a through hole 23 that is formed to pass through from the arrangement surface 21 to the connection surface 22 of the circuit board 2a near a mounting position of the surface mounted LED 33 on the circuit board 2a. In this case, as shown in FIGS. 12 and 13, the through hole 23 is, as an example, formed in a rectangular shape in a plan view. Further, as shown in FIG. 14, the light L is emitted from the surface mounted LED 33 and is reflected by the inner surface 53 (that corresponds to a reflective member) of the main plate 51 of the chassis 3. The through hole 23 is regulated with respect to its size and position so as to make the light L pass through from the connection surface 22 to the arrangement surface 21 of the circuit board 2a. As a result, it is possible to irradiate the light L toward an open area 3a of the chassis 3 as explained below.

In this case, in the power supply device 10, the surface mounted LED 33 is used as the light emitting component for confirming an operation of the power supply device 10. As a result, mounting can be effectively performed with a mounter for mounting a surface mounted component. Therefore, the manufacturing efficiency can be improved as compared with a case in which an insertion mounted LED that has a connection terminal formed with a metal wire material is used.

As shown in FIG. 8, the chassis 3 is provided with the main plate 51 and side walls 52a-52c that are respectively established on three outer circumference edges 51a-51c of the main plate 51. Further, the chassis 3 is configured so as to be able to hold the power supply circuit mounting body 2 on which the circuit components 31, the connectors 32 and the surface mounted LED 33 are mounted. In this case, a circumference edge 51d of the main plate 51 corresponds to the open area 3a that is open without a side wall. In a state in which the power supply circuit mounting body 2 is held by the chassis 3, the connector 32 that is mounted on the circuit board 2a is exposed at the open area 3a.

The main plate 51 and the side walls 52a-52c explained above are, as an example, integrally formed as the chassis 3 by pressing a steel plate. In the power supply device 10, as shown in FIG. 14, the inner surface of the main plate 51 works as the reflective member that makes the light L, which is emitted from the surface mounted LED, reflect. Therefore, as a metal plate that forms the chassis 3, it is preferred that the chassis 3 that is made of, for example, a steel plate that is plated by high-light reflective plating processes (for instance, a zinc luster chromate plating process, a luster tin plating process, a nickel plating process or a chrome plating process) is used.

In this case, in the power supply device 10, the main plate 51 of the chassis 3 works as the reflective member. Therefore, as compared with a configuration in which the reflective member, which is separately formed as another member that is different from the main plate 51, is provided on the inner surface of the main plate 51, it is possible to reduce the manufacturing costs of the power supply device 10, because the additional reflective member is not used.

Next, a method of using and operating the power supply device 10 will be explained below with reference to the drawings.

The power supply device 10 is, for instance, used by being attached to a cabinet or a rack. In this case, from the point of workability when a power cable is connected to the connector 32 of the power supply device 10, the power supply device 10 is placed and attached so as to make the connector 32 face to a front side (a near side) of the cabinet and the rack.

Next, the power supply device 10 is operated by connecting the power cable to the connector 32. Then, the power supply device 10 starts to supply electric power. As a result, the LED element 41a of the surface mounted LED 33 emits the light L according to an operation state of the power source circuit and the light L is emitted from the top surface 41d.

In the above case, the light that is emitted from the top surface 41d is reflected by the inner surface 53 of the main plate 51 of the chassis 3 that faces the connection surface 22 of the circuit board 2a on which the surface mounted LED 33 is placed.

The light L is emitted from the surface mounted LED 33 that is mounted on the connection surface 22 (a rear surface) of the circuit board 2a and is reflected by the inner surface 53 of the main plate 51 of the chassis 3. Because the through hole 23 is formed in the circuit board 2a, a part of the light L passes through the through hole 23 and reaches a side of the arrangement surface 21 (a front surface) of the circuit board 2a. Then, the light L is irradiated toward the open area 3a of the chassis 3.

Next, the light L (that is, a light emitting state of the surface mounted LED 33) emitted from the surface mounted LED 33 that is irradiated as explained above is visually recognized from the side of the open area 3a of the chassis 3. As a result, the operation state of the power source circuit may be confirmed.

As discussed above, in the power supply device according to the second embodiment of the present invention, a light emitting component for confirming an operation of the power supply device is composed of the surface mounted LED 33. The surface mounted LED 33 is placed on the connection surface 22 (a rear surface) of the circuit board 2a. Unlike a configuration in which an insertion mounted LED has a connection terminal formed by a metal wire material, an automated mounting process can be used for the surface mounted LED 33 by using, for example, a mounter. As a result, the manufacturing efficiency can be improved. Further, in the power supply device 10 according to the second embodiment of the present invention, because the through hole 23 is formed in the circuit board 2a, the light L, which is emitted from the surface mounted LED 33 that is mounted on the connection surface 22 of the circuit board 2a, is reflected by the reflective member (the inner surface 53 of the main plate 51) so as to pass the reflected light L through the through hole 23. Therefore, the reflected light L reaches the side of the arrangement surface 21 (a front surface) of the circuit board 2a. As a result, the light L can be irradiated toward the open area 3a of the chassis 3. Therefore, according to the power supply device 10, the visibility of the light L that is emitted from the surface mounted LED 33 as a light emitting component can be adequately secured. As a result, when a user looks at the circuit board 2a from the open area 3a of the chassis 3, the user can certainly and visually recognize a light emitting state of the surface mounted LED 33. Therefore, an operation state of the circuit board 2a on which the power supply device and/or the power source circuit are mounted can be surely confirmed.

In the power supply device 10 according to the second embodiment, the reflective member is the inner surface 53 of the main plate 51 in the chassis 3. Thus, as compared with a configuration in which the reflective member is formed by a separate member that is different from the inner surface 53 of the main plate 51 in the chassis 3, it is possible to reduce the manufacturing costs of the power supply device 10 because the separate reflective member is not necessary.

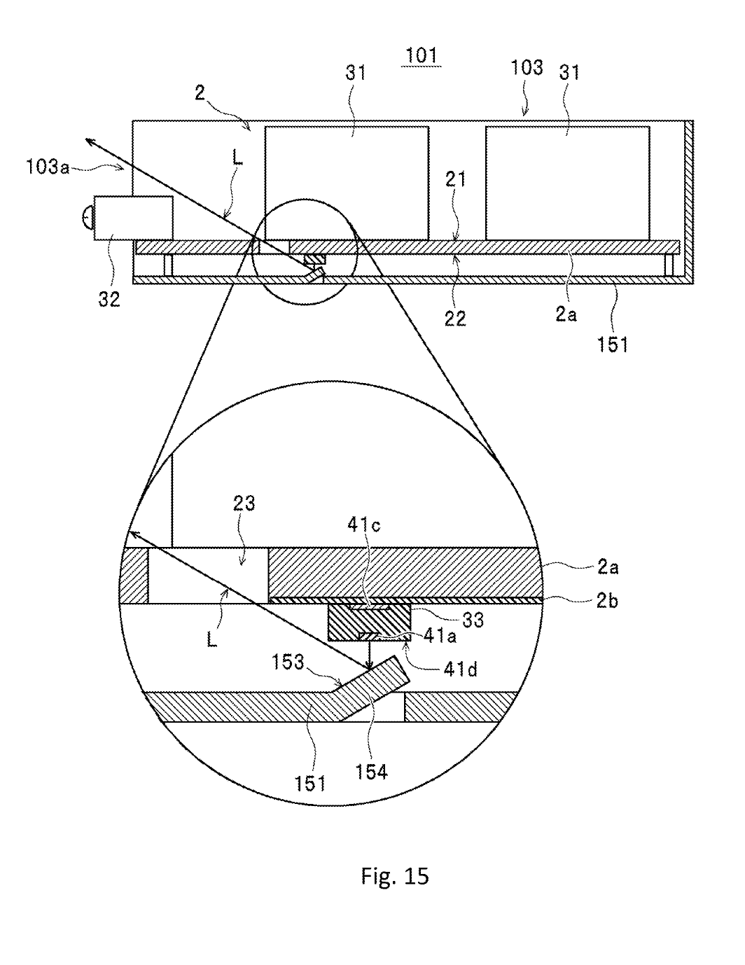

The above configurations of the reflective member and the through hole 23 through which the light that is reflected by the reflective member passes are not limited to the embodiment explained above. For instance, a power supply device 101 shown in FIG. 15 can also be adopted. A repeated explanation is omitted by using the same reference numerals for the same parts as in the power supply device 10. In the power supply device 101, as shown in FIG. 15, a part of a main plate 151 of a chassis 103 is cut off and is bent so as to tilt from other parts of the main plate 151. Further, an inner surface 153 of the bent part explained above (also referred to as “a tilt part 154” below) functions as the reflective member. In this case, the most of the light L that is emitted from the surface mounted LED 33 can be reflected toward the through hole 23 by adjusting an angle of the tilt part 154. Therefore, much of the light L can be irradiated toward an open area 103a of the chassis 103. As a result, the light emitting state of the surface mounted LED 33 can be visually recognized more certainly. Further, in the power supply device 101, the inner surface 153 of the tilt part 154 that corresponds to a part of the chassis 103 functions as the reflective member. Therefore, as explained above, it is preferred that the chassis 103 is made of a steel plate that is plated with a high-light reflective plating process.

Instead of the configuration in which the main plates 51 and 151 function as the reflective member as explained above, a configuration in which a reflective member that is separately formed and that is different from the main plates 51 and 151 is placed on a side of the inner surfaces 53 and 153 of the main plates 51 and 151, can also be adopted.

Further, although the through hole 23 is formed in the rectangular shape in the plan view as explained above, the shape of the through hole 23 in the plan view is not limited to the rectangular shape. The through hole 23 can be formed in an arbitrary shape such as a circular shape (or a semicircular shape), an elliptical shape (or a semielliptical shape), a square shape, a slit shape or a mesh shape.

Further, although the chassis 103 in which a top area that is opposite to the main plate 51 is open as explained above is used, a configuration in which a cover for covering the top open area can be provided, i.e., a configuration, in which a casing that has a chassis 103 and the cover are used, can also be adopted.

The power supply device being thus described, it will be apparent that the same may be varied in many ways. Such variations are not to be regarded as a departure from the spirit and scope of the invention, and all such modifications as would be apparent to one of ordinary skill in the art are intended to be included within the scope of the following claims.

What is claimed is:

1. A power supply device, comprising:
a circuit board including:
an arrangement surface;
a rear surface on an opposite side of the circuit board as the arrangement surface;
a through hole extending from the arrangement surface to the rear surface; and
an insertion mounted circuit component, a connector and a surface mounted light emitting component that is provided for confirming an operation state of the power supply device mounted thereon; and
a chassis that holds the circuit board from sides and the rear surface of the circuit board, the chassis having an opening that exposes the connector, wherein
the surface mounted light emitting component is surface mounted on the rear surface of the circuit board, and
the through hole is provided proximate the surface mounted light emitting component so as to guide light emitted from the surface mounted light emitting component toward the opening of the chassis.

2. The power supply device according to claim 1, wherein
the surface mounted light emitting component is a light emitting diode.

3. The power supply device according to claim 1, wherein
the surface mounted light emitting component is configured with a light emitting member and an optical dispersion member operably associated with the light emitting member, and
an edge of the optical dispersion member is located inside the through hole in a plan view.

4. The power supply device according to claim 3, wherein
the light emitting member is a light emitting diode.

5. A power supply device, comprising:
a circuit board including:
an arrangement surface;
a rear surface on an opposite side of the circuit board as the arrangement surface;
a through hole extending from the arrangement surface to the rear surface; and
an insertion mounted circuit component, a connector and a surface mounted light emitting component that is provided for confirming an operation state of the power supply device mounted thereon;
a chassis that holds the circuit board from sides and the rear surface of the circuit board, the chassis including:
an opening that exposes the connector; and
a reflective member facing the rear surface of the circuit board and the surface mounted light emitting component; and
a gap that is provided between the rear surface of the circuit board and the reflective member, wherein
the surface mounted light emitting component is surface mounted on the rear surface of the circuit board so as to emit light toward the reflective member, and
the through hole is provided proximate the surface mounted light emitting component so as to guide the light reflected by the reflective member toward the opening of the chassis.

6. The power supply device according to claim 5, wherein
the surface mounted light emitting component is a light emitting diode.

7. The power supply device according to claim 5, wherein
the reflective member is a surface of the chassis.

8. The power supply device according to claim 5, wherein
the reflective member is at a bottom plate of the chassis and is a bent part of the bottom plate that is angled toward the surface mounted light emitting component.
